(19) United States
(12) Patent Application Publication
(10) Pub. No.: US 2007/0165754 A1
(43) Pub. Date: Jul. 19, 2007

(54) Method for avoiding interference from a cellular transmitter to the 2.4/5GHz ISM band

(76) Inventors: Niko Kiukkonen, Veikkola (FI); Jari Junell, Vantaa (FI)

Correspondence Address: MORGAN & FINNEGAN, LLP, 3 World Financial Center, New York, NY, 10281-2101, US

(21) Appl. No.: 11/332,172

(22) Filed: Jan. 17, 2006

(51) Int. Cl. H03D 1/04

(52) U.S. Cl. 375/346

(57) ABSTRACT

A method, terminal, and computer program are disclosed to reduce radio interference in a wireless communications device having a combination of a wireless telephone unit, such as a GSM cellular phone, and a short range wireless communications unit, such as a WLAN communications unit or a Bluetooth communications unit. An interference avoidance subsystem in the wireless communications device is connected between the GSM frequency hopping logic and the Bluetooth frequency hopping logic. Bluetooth frequency hopping information and time domain operation information are input from the Bluetooth frequency hopping logic to the interference avoidance subsystem. GSM frequency hopping information and time domain operation information are input from the GSM frequency hopping logic to the interference avoidance subsystem. The interference avoidance subsystem then uses this input data to calculate the interference probability between co-existing Bluetooth received signals and GSM transmitted signals. The interference avoidance subsystem then compares the calculated interference probability with the required Bluetooth packet error rate limit for the current application. If the interference probability exceeds the required Bluetooth packet error rate limit, the interference avoidance subsystem sends a signal to the Bluetooth frequency hopping logic to change the Bluetooth frequencies.

### FIELD OF THE INVENTION

The invention disclosed broadly relates to improvements in mobile terminals having combined functions of cellular telephone with Wireless LAN and/or Bluetooth interfaces, for reducing interference in simultaneous signal handling of cellular telephone and either WLAN or Bluetooth signals.

### BACKGROUND OF THE INVENTION

The GSM (Global System for Mobile Communications) System

GSM-900 and GSM-1800 are used in most of the world. GSM-900 uses 890-915 MHz to send information from the Mobile Station to the Base Transceiver Station (uplink) and 935 -960 MHz for the other direction (downlink), providing 124 RF channels spaced at 200 kHz. Duplex spacing of 45 MHz is used. GSM-1800 uses 1710 -1785 MHz to send information from the Mobile Station to the Base Transceiver Station (uplink) and 1805 -1880 MHz for the other direction (downlink), providing 299 channels. Duplex spacing is 95 MHz. GSM-1800 is also called PCS in Hong Kong and the United Kingdom.

GSM-850 and GSM-1900 are used in the United States, Canada, and many other countries in the Americas. GSM-850 is also sometimes called GSM-800. GSM-850 uses 824-849 MHz to send information from the Mobile Station to the Base Transceiver Station (uplink) and 869 -894 MHz for the other direction (downlink). GSM-1900 uses 1850 -1910 MHz to send information from the Mobile Station to the Base Transceiver Station (uplink) and 1930-1990 MHz for the other direction (downlink). Despite the close number, GSM 850 is not compatible with GSM 900; a phone that only has GSM 850 cannot work on a GSM 900 network, and vice-versa.

GSM Frequency Hopping

A GSM base station and its GSM mobile stations in a cell average their signal propagation characteristics over all the available frequencies of the cell by employing slow frequency hopping (SFH). In SFH, the operating frequency is changed only with every TDMA frame. The hopping rate is one hop per TDMA frame (4.6 millisecond) or 217 hops per second. The frequency change in SFH can be handled by the synthesizers in the GSM mobile station, which are also required to alter their operating frequency even more often than once per TDMA frame to enable them to monitor adjacent cells, as well as perform frequency hopping.

Frequency hopping is an option for the GSM base station in each individual cell. However, a GSM mobile station is required to switch to a frequency-hopping mode when its GSM base station tells it to do so. Originally, the GSM system was designed so that the mobile would perform the frequency hopping operation when the channel became marginal, such as when it moved toward the edge of a cell or as it entered an area of high interference. Currently, GSM networks utilize frequency hopping all the time, not only in the case of interference. The GSM base station controller assigns to the mobile a full set of RF channels rather than a single RF channel. The GSM mobile performs the frequency hopping operation on the assigned set of frequencies to satisfy the command from the base station.

Different hopping algorithms can be assigned to the GSM mobile station with the channel set. One is cyclic hopping, in which hopping is performed through the assigned frequency list from the first frequency, the second frequency, the third, and so on until the list is repeated. The other general algorithm is (pseudo) random hopping, in which hopping is performed in a random way through the frequency list. There are 63 different random hopping sequences that can be assigned to the GSM mobile. When the GSM base station requires the mobile station to assume SFH operation, the GSM mobile station is advised of the channel assignment (a set of channels) and which one of the hopping algorithms it should use with an appropriate frequency-hopping sequence number (HSN).

The Unlicensed 2.4 GHz ISM Band

The two methods for radio frequency modulation in the unlicensed 2.4 GHz ISM band are frequency-hopping spread spectrum (FHSS) and direct-sequence spread spectrum (DSSS). Bluetooth uses FHSS while Wireless LAN 802.11b/g/a (commonly known as Wi-Fi) use DSSS/OFDM. All of these technologies operate in the ISM frequency band (2.400 to 2.483 GHz), which is available worldwide.

Bluetooth

The best-known example of wireless personal area network (PAN) technology is the Bluetooth Standard, which operates in the 2.4 GHz ISM band. Bluetooth is a short-range radio network, originally intended as a cable replacement. It can be used to create ad hoc networks of up to eight devices operating together. The Bluetooth Special Interest Group, Bluetooth Specification Including Core, Volume 1.2, Nov. 5, 2003, (hereinafter “Bluetooth 1.2 Specification”) describes the principles of Bluetooth device operation and includes a description of adaptive frequency hopping. Specification of the Bluetooth Systemy, Covered Core Package, version: 2.0+EDR, issued 4 Nov. 2004 (hereinafter “Bluetooth 2.0 Specification”) further describes the principles of Bluetooth device operation and includes a further description of adaptive frequency hopping. Bluetooth Specifications are available from the Bluetooth Special Interest Group at the web site www.bluetooth.com. Bluetooth devices are designed to find other Bluetooth devices and access points within their ten meter radio communications range.

Bluetooth operates in the ISM frequency band starting at 2.402 GHz and ending at 2.483 GHz in the USA, and Europe. There are 79 RF channels of 1 MHz width defined. The air interface is based on an antenna power of 1 mW (0 dBi gain). The signal is modulated using binary Gaussian Frequency Shift Keying (GFSK). The raw data rate is defined at 1 Mbits/s. A Time Division Multiplexing (TDM) technique divides the channel into 625 microsecond slots. Transmission occurs in packets that occupy an odd number of slots (up to 5). Each packet is transmitted on a different hop frequency with a maximum frequency hopping rate of 1600 hops/s.

Two or more units communicating on the same channel form a piconet, where one unit operates as a master and the others (a maximum of seven active at the same time) act as slaves. A channel is defined as a unique pseudo-random frequency hopping sequence derived from the master device's 48-bit address BD_ADDR and its Bluetooth clock value. Slaves in the piconet synchronize their timing and frequency hopping to the master upon connection establishment. In the connection mode, the master controls the access to the channel using a polling scheme where master and slave transmissions alternate. A slave packet always follows a master packet transmission

Bluetooth Frequency Hopping

Adaptive frequency hopping is a new feature introduced in the Bluetooth Core Specification 1.2, Section 2.The adapted piconet physical channel are uses at least 20 RF channels. Adapted piconet physical channels can be used for connected devices that have adaptive frequency hopping (AFH) enabled. There are two distinctions between basic and adapted piconet physical channels. The first is that the same channel mechanism that makes the slave frequency the same as the preceding master transmission. The second aspect is that the adapted piconet physical channel may be based on less than the full 79 frequencies of the basic piconet physical channel. Bluetooth devices use a hopping kernel that controls an adapted set of hop locations used by adaptive frequency hopping (AFH). The basic, legacy channel hopping sequence which has a very long period length, which does not show repetitive patterns over a short time interval, and which distributes the hop frequencies equally over the 79 MHz during a short time interval. An adapted channel hopping sequence is derived from the basic channel hopping sequence which uses the same channel mechanism and may use fewer than 79 frequencies. The adapted channel hopping sequence is only used in place of the basic channel hopping sequence, not the hopping sequences for inquiry or paging functions. When the adapted channel hopping sequence is selected, the AFH_channel_map is an input to the frequency selection. The AFH_channel_map indicates which channels are used and which are unused. The output, RF channel index, constitutes a pseudo-random sequence. The RF channel index is mapped to RF channel frequencies The selection scheme chooses a segment of 32 hop frequencies spanning about 64 MHz and visits these hops in a pseudo-random order. Next, a different 32-hop segment is chosen, etc. When the basic channel hopping sequence is selected, the output constitutes a pseudo-random sequence that slides through the 79 hops. The RF frequency remains fixed for the duration of the packet. The RF frequency for the packet is derived from the Bluetooth clock value in the first slot of the packet. When the adapted channel hopping sequence is used, the pseudo-random sequence contains only frequencies that are in the RF channel set defined by the AFH_channel_map input. The adapted sequence has similar statistical properties to the non-adapted hop sequence. In addition, the slave responds with its packet on the same RF channel that was used by the master to address that slave. Thus, the RF channel used for the master to slave packet is also used for the immediately following slave to master packet. The output addresses a bank of 79 registers loaded with the synthesizer code words corresponding to the hop frequencies 0 to 78.The adapted hop selection kernel is based on the basic hop selection kernel. The inputs to the adapted hop selection kernel are the same as for the basic hop system kernel except that the input AFH_channel_map is used. The AFH_channel_map indicates which RF channels are used and which are unused. When hop sequence adaptation is enabled, the number of used RF channels may be reduced from 79 to some smaller value N. All devices are capable of operating on an adapted hop sequence (AHS) with 20≦N≦79, with any combination of used RF channels within the AFH_channel_map that meets this constraint. Adaptation of the hopping sequence is achieved through two additions to the basic channel hopping sequence. Unused RF channels are re-mapped uniformly onto used RF channels. That is, if the hop selection kernel of the basic system generates an unused RF channel, an alternative RF channel out of the set of used RF channels is selected pseudo-randomly. The used RF channel generated for the master-to-slave packet is also used for the immediately following slave-to-master packet. When the adapted hop selection kernel is selected, the basic hop selection kernel is initially used to determine an RF channel. If this RF channel is unused according to the AFH_channel_map, the unused RF channel is re-mapped by the re-mapping function to one of the used RF channels. If the RF channel determined by the basic hop selection kernel is already in the set of used RF channels, no adjustment is made. The hop sequence of the (non-adapted) basic hop equals the sequence of the adapted selection kernel on all locations where used RF channels are generated by the basic hop. This property facilitates non-AFH slaves remaining synchronized while other slaves in the piconet are using the adapted hopping sequence. The re-mapping function is a post-processing step to the selection kernel. The output of the basic hop selection kernel is an RF channel number that ranges between 0 and 78.This RF channel will either be in the set of used RF channels or in the set of unused RF channels. When an unused RF channel is generated by the basic hop selection mechanism, it is re-mapped to the set of used RF channels. The index is then used to select the re-mapped channel from a mapping table that contains all of the even used RF channels in ascending order followed by all the odd used RF channels in ascending order. In the basic and adapted channel hopping sequences, the clock bits to use in the basic or adapted hopping sequence generation are always derived from the master clock, CLK. The address bits are derived from the Bluetooth device address of the master.

IEEE 802.11 Wireless LAN Standard

Wireless local area networks (WLAN) cover a larger radio communications range of up to one hundred meters. Examples of wireless local area network technology include the IEEE 802.11 Wireless LAN Standard, which also operates in the 2.4 GHz ISM band. The IEEE 802.11 Wireless LAN Standard is published in three parts as IEEE 802.11-1999; IEEE 802.11a-1999; and IEEE 802.11b-1999, which are available from the IEEE, Inc. web site http://grouper.ieee.org/groups/802/11.

The IEEE 802.11 standard calls for four different PHY specifications: frequency hopping (FH) spread spectrum, direct sequence (DS) spread spectrum, infrared (IR), and orthogonal frequency division multiplex (OFDM). The transmit power for DS and FH devices is defined at a maximum of 1 W and the receiver sensitivity is set to −80 dBm. Antenna gain is limited to 6 dBi maximum. Under FH, each station's signal hops from one modulating frequency to another in a predetermined pseudo-random sequence. Both transmitting and receiving stations are synchronized and follow the same frequency sequence. There are 79 channels defined in the (2.4000 -2.4835) GHz region spaced 1 MHz apart. The time each radio dwells on each frequency depends on each individual implementation and government regulation. The basic access rates of 1 and 2 Mbits/s use multilevel Gaussian frequency shift keying (GFSK).

The IEEE 802.11 b specification sets up 11 channels within the 2.4-GHz band, centered between 2.412 and 2.462 GHz. Although the IEEE 802.11 standard includes a frequency hopping (FH) spread spectrum protocol, it is typically applied using only a single channel frequency.

Combined Cellular Telephone, an Integrated WLAN 802.11b, and a Bluetooth

The newest mobile telephones and personal digital assistants combine a cellular telephone, an Integrated WLAN 802.11b, and a Bluetooth personal area network functionality into a single, portable package. A problem is that the cellular transmission at the Cell band's lowest 3.5 MHz frequency block (824-827 MHz) causes a 3rd order harmonic to result on top of the uppermost frequencies of the 2.4 GHz ISM band. GSM transmissions, for instance, are blocking the 10 MHz frequency block (2470-2480 MHz) at the top end of the ISM band. This ISM band is used in terminals for both Bluetooth and WLAN radio transmission and reception. Similarly, GSM1800/PCS1900 transmissions in the USA, create a 3rd harmonic signal that blocks 5 GHz ISM band reception (WLAN, 802.11a).

The ISM band utilization is heavily increasing. The new services like VoWLAN, (voice over WLAN) are utilizing the same frequencies as Bluetooth and, for example, microwave ovens. In addition, the WLAN and Bluetooth usage scenarios are typically sharing the same physical location (such as an office environment). The problem is that the available unregulated frequencies at 2.4 GHz are running out. There is currently a 79 MHz allocation out of which each WLAN access point is utilizing 20 MHz slice. Bluetooth adaptive frequency hopping requires at least 20 times a 1 MHz channel to operate. The prior art solution is continuously losing approximately 13% of Bluetooth channel capacity by restricting the usage of the 10 uppermost channels, even though the collision probability is low or nil. Another problem arises with certain WLAN protocols, where no frequency hopping is utilized. The cellular telephone transmitters are interfering with both the 2.4 GHz and 5 GHz WLAN operation.

Currently the situation is handled in the case of Bluetooth, by totally restricting the usage of the ten uppermost channels in case of the GSM850 signal being present in the same product. The ten uppermost Bluetooth frequencies are blocked without any check as to whether there is actually an interfering GSM signal present. The blocking of Bluetooth frequencies is based on the adaptive frequency hopping utilized in Bluetooth to avoid interference, such as from the 3rd harmonic of GSM signals or the co-existence with WLAN signals. There are other prior art solutions where the frequency hopping is controlled to use bad channels for less critical packets and good channels for critical packets, requiring a complex decision logic.

What is needed in the art is an improved method to reduce interference in simultaneous GSM cellular, WLAN and/or Bluetooth signal handling in a combined communications package.

### SUMMARY OF THE INVENTION

A method, terminal, and computer program are disclosed for a wireless communications device having a combination of a wireless telephone unit, such as a GSM cellular phone, and a short range wireless communications unit, such as a WLAN communications unit or a Bluetooth communications unit. The wireless telephone unit and Bluetooth communications unit use frequency hopping spread spectrum techniques to reduce interference from extraneous radio sources. The WLAN communications unit typically uses only a single channel frequency out of several available channels. Since the units are in close proximity to one-another in the wireless communications device, mutual radio interference can occur, either by the direct overlapping of the spectra of the wireless telephone unit with the short range wireless communications unit or by overlapping of the harmonic frequencies of one unit with the spectrum of the other unit.

This problem is solved in one embodiment of the invention by an interference avoidance subsystem in the wireless communications device, which is connected between the wireless telephone unit's frequency hopping logic and the short range wireless communications unit's logic. Frequency information and time domain operation information are input from the short range wireless communications unit logic to the interference avoidance subsystem. Frequency hopping information and time domain operation information are input from the wireless telephone unit's frequency hopping logic to the interference avoidance subsystem. The interference avoidance subsystem then uses this input data to calculate the interference probability between co-existing signals received by the short range wireless communications unit and signals transmitted from the wireless telephone unit. The interference avoidance subsystem then compares the calculated interference probability with the required error rate limit for the short range wireless communications unit. If the interference probability exceeds the required error rate limit, the interference avoidance subsystem sends a signal to either the short range wireless communications unit or to the wireless telephone unit to make a change to one of the co-existing signals.

One example that is addressed by the invention is the combination of a Bluetooth communications unit and a GSM cellular telephone unit in the wireless communications device. In the lower end of the GSM frequency spectrum, the third harmonic frequency of the range of 824-849 MHz for a GSM Mobile to Base transmission overlaps up to ten of the highest frequency Bluetooth channels in the ISM frequency spectrum of 2400-2483 MHz. Since the transmitted GSM telephone signals are stronger than received Bluetooth signals, interference occurs when the GSM signals frequency hop in the lower end of the GSM frequency spectrum and are transmitted while Bluetooth signals frequency hop and are received in the ten highest frequency channels in the ISM frequency spectrum.

This problem is solved in one embodiment of the invention by an interference avoidance subsystem in the wireless communications device, which is connected between the GSM frequency hopping logic and the Bluetooth frequency hopping logic. Bluetooth frequency hopping information and time domain operation information are input from the Bluetooth frequency hopping logic to the interference avoidance subsystem. GSM frequency hopping information and time domain operation information are input from the GSM frequency hopping logic to the interference avoidance subsystem. The interference avoidance subsystem then uses this input data to calculate the interference probability between co-existing Bluetooth received signals and GSM transmitted signals. The interference avoidance subsystem then compares the calculated interference probability with the required Bluetooth packet error rate limit for the current application. If the interference probability exceeds the required Bluetooth packet error rate limit, the interference avoidance subsystem sends a signal to the Bluetooth frequency hopping logic to change the Bluetooth frequencies. The interference avoidance subsystem calculates the probability of interference a priori. The interference avoidance subsystem uses this principle to limit the Bluetooth hopping frequencies by determining which channels are blocked by the GSM harmonics and then omitting as many of the blocked Bluetooth channels from the hopping sequence as needed to reach the required error rate criterion.

In another embodiment of the invention, the interference avoidance subsystem performs a loop to progressively remove the top frequency Bluetooth channels and to recalculate the interference probability until the magnitude of the interference probability is sufficiently reduced so as to not exceed the required error rate limit.

Another example that is addressed by the invention is the combination of a WLAN communications unit and a GSM cellular telephone unit in the wireless communications device. Although the IEEE 802.11 standard includes a frequency hopping (FH) spread spectrum protocol, it is typically applied using only a single channel frequency selected out a several available channels, so that the WLAN communications link does not engage in frequency hopping. In the case where the WLAN communications unit of the wireless communications device is not operating in a frequency hopping mode, the method of the invention operates, for example, as follows. The interference avoidance subsystem calculates the interference probability between co-existing WLAN received signals and GSM transmitted signals with the WLAN hopping frequencies set equal to one. If the calculated interference probability is greater than the predefined error probability or packet error rate limit, then the interference avoidance subsystem signals the WLAN communications unit to discard the WLAN reception packet. This results in the WLAN communications unit not transmitting an acknowledgement packet back to the sender. Typically, the WLAN protocol will then require the sender to retransmit the packet, which most probably will not occur simultaneously with following GSM transmissions and will be correctly received. The number of GSM hopping frequencies used by the interference avoidance subsystem in calculating the interference probability with WLAN signals is similar to that previously discussed above in the case of Bluetooth. The GSM hopping frequencies used in calculating the interference probability the depend on the GSM operator frequency allocation and the number of frequencies in the hopping sequence causing an intermodulation distortion (IMD) result on top of the WLAN reception.

In another embodiment of the invention, only if the received packet is detected by the WLAN communications unit as being corrupted, will the packet be discarded. If the reception packet detected by the WLAN communications unit is not corrupted, then the received packet may be suspected of containing erroneous data. Optionally, the WLAN communications unit can discard the WLAN reception packet in this case, as well, and force a retransmission of the packet from the sender. In still another embodiment, the WLAN communications unit can direct a received WLAN packet that is suspected of containing erroneous data, into a suspicious-packet-buffer for additional error checking or tagging.

In another embodiment of the invention where the WLAN communications link does not engage in frequency hopping, interference with a WLAN reception packet is avoided by the interference avoidance subsystem signaling the GSM communications unit to suppress transmission a GSM packet if it will interfere with the WLAN reception packet.

Further in accordance with another embodiment of the invention, the interference avoidance subsystem can compare a Quality-of-Service parameter for the WLAN communications link with a Quality-of-Service parameter for the GSM link to determine whether potentially interfering WLAN reception packets should be discarded, as opposed to an alternative mode of the interference avoidance subsystem signaling the GSM communications unit to suppress transmission a GSM packet if it will interfere with a WLAN reception packet.

In another embodiment of the invention, the short range wireless communications unit can input a received signal quality value in the calculation of the interference probability, for signals received by the short range wireless communications unit.

In another embodiment of the invention, the interference avoidance subsystem can calculate an instant when the interference will occur. In response, the interference avoidance subsystem will change one of the co-existing signals at that instant if the interference probability exceeds the required error rate limit.

The resulting invention can be applied to interference between the frequency spectra of WLAN communication units such as the IEEE 802.11a, b, and/or g, and GSM cellular telephone units, both of which are in the same wireless communications device. The invention can also be applied to interference between the frequency spectra of WLAN communication units such as the IEEE 802.11a, b, and/or g, and Bluetooth communication units, both of which are in the same wireless communications device.

### DESCRIPTION OF THE FIGURES

FIG. 1 is a network diagram showing a GSM/WLAN/Bluetooth wireless communications device having a combination of a GSM cellular telephone transceiver, a WLAN transceiver, and a Bluetooth transceiver, the wireless communications device being wirelessly connected to a Bluetooth headset, to a WLAN access point, and to a GSM base station, according to an embodiment of the present invention.

FIG. 2A is a diagram of the frequency spectrum for a 824-849 MHz GSM Mobile to Base transmission and the overlap of its third harmonic with the frequency spectrum for a 2400-2483 MHz ISM (Bluetooth & 802.11) transmission, according to an embodiment of the present invention.

FIG. 2B is a diagram of the frequency spectrum for a 1710-1785 MHz GSM Mobile to Base transmission and the overlap of its third harmonic with the frequency spectrum for a 5725-5850 MHz ISM (802.11) transmission, according to an embodiment of the present invention.

FIG. 3 is a network diagram that shows the wireless network relationship of the Bluetooth Headset, the GSM/WLAN/Bluetooth wireless communications device, and the GSM Base Station, according to an embodiment of the present invention.

FIG. 4 is a functional block diagram of the GSM/WLAN/Bluetooth wireless communications device, including an interference avoidance subsystem connected between a GSM frequency hopping logic and a Bluetooth frequency hopping logic, according to an embodiment of the present invention.

FIG. 5 is a flow diagram of the operation of the interference avoidance subsystem in the GSM/WLAN/Bluetooth wireless communications device for received Bluetooth signals, according to an embodiment of the present invention.

FIG. 6 is a more detailed functional block diagram of the GSM/WLAN/Bluetooth wireless communications device, showing how the interference avoidance subsystem interacts with the Bluetooth frequency hopping logic and the GSM frequency hopping logic to carry out the operation of the flow diagram of FIG. 5, according to an embodiment of the present invention.

FIGS. 7A to 7D are tables showing the calculated interference probability computed by the interference avoidance subsystem for the case where the wireless communications device transmits a GSM signal using a 5 MHz operator frequency allocation (TX: 824-829 MHz) for hopping (25 channels) and the wireless communications device receives Bluetooth signals at various example hopping frequencies (min 20, max 79), according to an embodiment of the present invention.

FIG. 8A is a diagram of the frequency spectrum for a 850-875 MHz GSM Mobile to Base transmission, showing that there is no overlap of its third harmonic with the frequency spectrum for signals received in the 2400-2483 MHz ISM (Bluetooth & 802.11) spectrum and thus, in this case, the interference probability computed by the interference avoidance subsystem does not exceed the required Bluetooth packet error rate limit, and therefore the full 2400 to 2483 MHz ISM spectrum is available for Bluetooth frequency hopping, according to an embodiment of the present invention.

FIG. 8B is a diagram of the frequency spectrum for a 824-849 MHz GSM Mobile to Base transmission, showing that there is an overlap of its third harmonic with the frequency spectrum for signals received in the 2400-2483 MHz ISM (Bluetooth & 802.11) spectrum and thus, in this overlapped case, the interference probability computed by the interference avoidance subsystem exceeds the required packet error rate limit, and therefore the process shown in the flow diagram of FIG. 5 limits the Bluetooth hopping frequencies by calculating which channels are blocked by the GSM harmonics and then omitting as many of the blocked Bluetooth channels from the hopping sequence as needed to reach the required error rate criterion, according to an embodiment of the present invention.

FIG. 9 is a network diagram that shows the wireless network relationship of the WLAN access point, the GSM/WLAN/Bluetooth wireless communications device, and the GSM Base Station, according to an embodiment of the present invention.

FIG. 10 is a functional block diagram of the GSM/WLAN/Bluetooth wireless communications device, including an interference avoidance subsystem connected between a GSM frequency hopping logic and a WLAN frequency hopping logic, according to an embodiment of the present invention.

FIG. 11 is a flow diagram of the of the operation of the interference avoidance subsystem in the GSM/WLAN/Bluetooth wireless communications device for WLAN received signals without frequency hopping, according to an embodiment of the present invention.

FIGS. 12A and 12B are tables showing the calculated interference probability computed by the interference avoidance subsystem for the case where the wireless communications device transmits a GSM signal using a 5 MHz operator frequency allocation (TX: 824-829 MHz) for hopping (25 channels) and the wireless communications device receives WLAN VoIP signals, according to an embodiment of the present invention.

### DISCUSSION OF THE PREFERRED EMBODIMENT

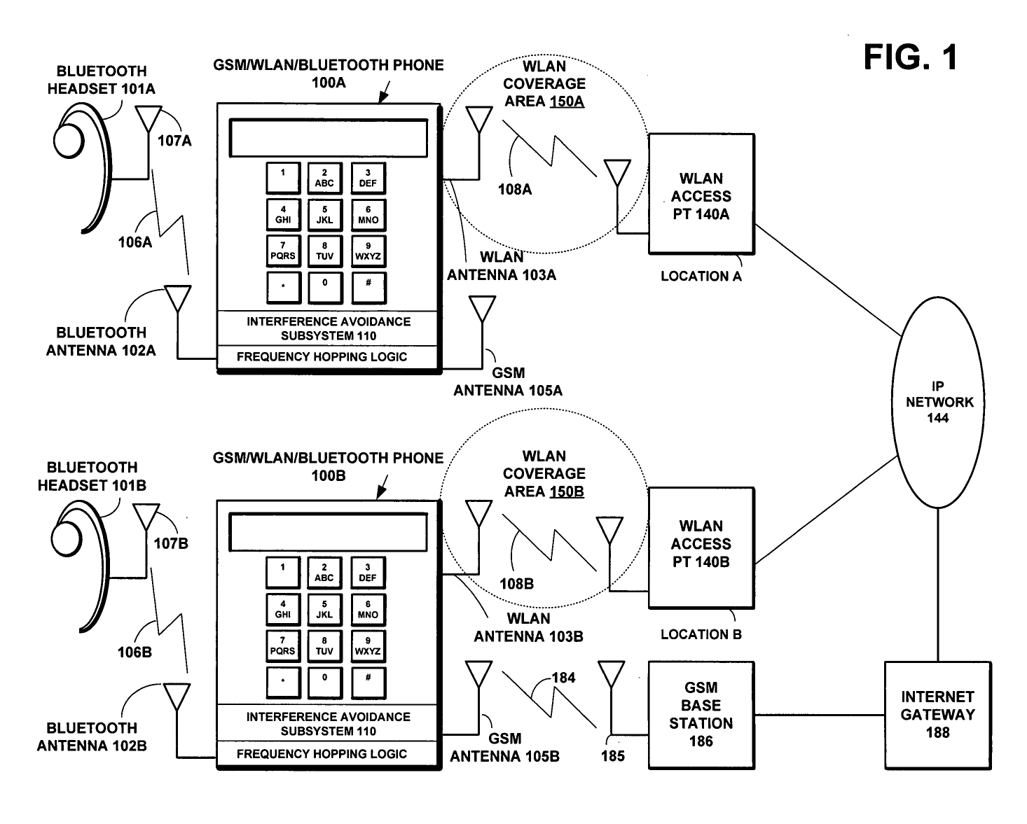

FIG. 1 is a network diagram showing a GSM/WLAN/Bluetooth wireless communications device 100B having a combination of a GSM cellular telephone unit, a WLAN communications unit, and a Bluetooth communications unit. The wireless communications device 100B is wirelessly connected via Bluetooth antenna 102B to a Bluetooth headset 101B and its antenna 107B over wireless path 106B. The wireless communications device 100B is wirelessly connected via WLAN antenna 103B to a WLAN access point 140B in WLAN coverage area 150B over wireless path 108B. The wireless communications device 100B is wirelessly connected via GSM antenna 105B to a GSM base station 186 and its antenna 185 over wireless path 184, according to an embodiment of the present invention. A similar second GSM/WLAN/Bluetooth wireless communications device 100A is shown wirelessly connected via Bluetooth antenna 102A to a Bluetooth headset 101A and its antenna 107A over wireless path 106A and connected via WLAN antenna 103A to a WLAN access point 140A in WLAN coverage area 150A over wireless path 108A. The wireless communications device 100B in FIG. 1 includes the microbrowser, a key pad, interference avoidance subsystem 110, and frequency hopping logic. The WLAN access points 140A and 140B are connected to the internet 144, which is connected in turn to the WAP protocol internet gateway 188, which in turn is connected to the GSM access point 186.

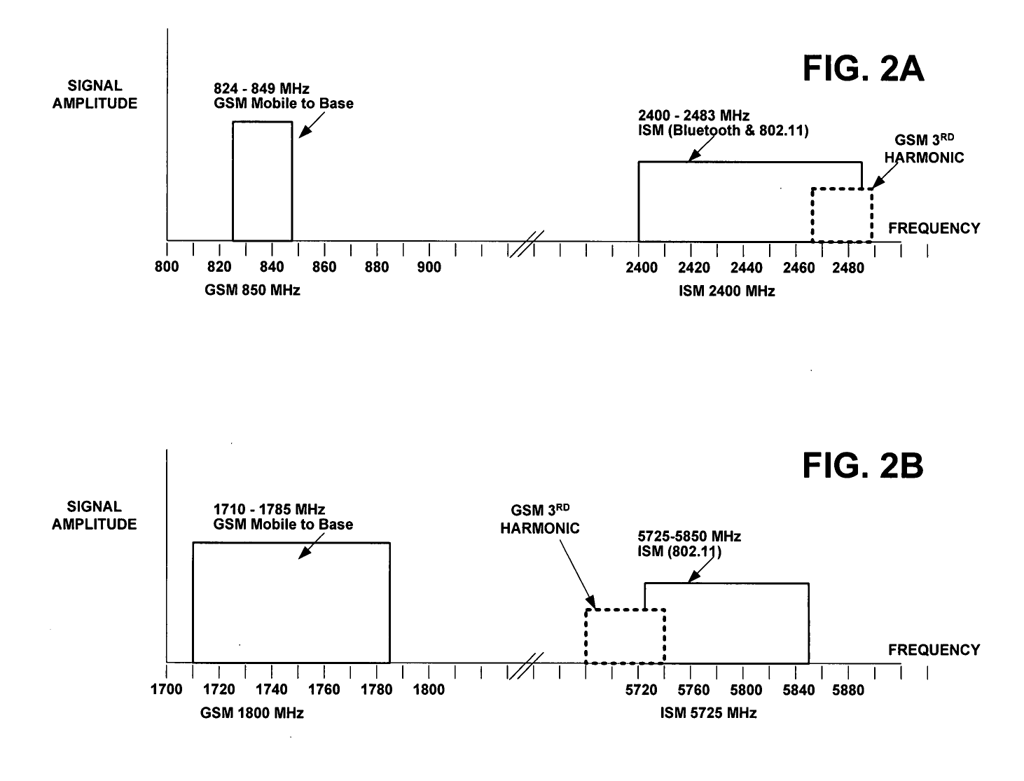

FIG. 2A is a diagram of the frequency spectrum for a 824-849 MHz GSM Mobile to Base transmission and the overlap of its third harmonic with the frequency spectrum for a 2400-2483 MHz ISM (Bluetooth & 802.11) transmission, according to an embodiment of the present invention. The combination of a Bluetooth communications unit and a GSM cellular telephone unit in the wireless communications device can create radio interference in certain frequency hopping combinations. In the lower end of the GSM frequency spectrum, the third harmonic frequency of the range of 824-849 MHz for a GSM Mobile to Base transmission overlaps up to ten of the highest frequency Bluetooth channels in the ISM frequency spectrum of 2400-2483 MHz. Since the transmitted GSM telephone signals are stronger than received Bluetooth signals, interference occurs when the GSM signals frequency hop in the lower end of the GSM frequency spectrum and are transmitted while Bluetooth signals frequency hop and are received in the ten highest frequency channels in the ISM frequency spectrum.

FIG. 2B is a diagram of the frequency spectrum for a 1710-1785 MHz GSM Mobile to Base transmission and the overlap of its third harmonic with the frequency spectrum for a 7525-5850 MHz ISM (802.11) transmission, according to an embodiment of the present invention.

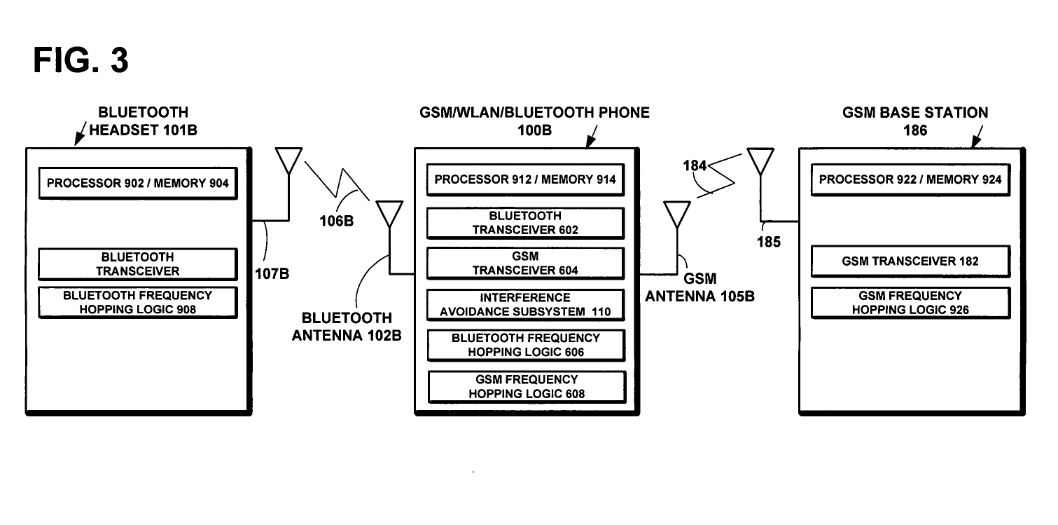

FIG. 3 is a network diagram that shows the wireless network relationship of the Bluetooth Headset 101B, the GSM/WLAN/Bluetooth wireless communications device 100B and the GSM Base Station 186, according to an embodiment of the present invention. The Bluetooth Headset 101B includes a processor 902 that executes program instructions stored in the memory 904 to carry out the functions of the Bluetooth Headset 101B. The Bluetooth Headset 101B also includes a Bluetooth transceiver and Bluetooth frequency hopping logic 908. The GSM/WLAN/Bluetooth wireless communications device 100B includes a processor 912 that executes program instructions stored in the memory 914 to carry out the functions of the wireless communications device 100B. The wireless communications device 100B also includes a Bluetooth transceiver 602, a GSM transceiver 604, interference avoidance subsystem 110, Bluetooth frequency hopping logic 606, and GSM frequency hopping logic 608.The GSM Base Station 186 includes a processor 922 that executes program instructions stored in the memory 924 to carry out the functions of the GSM Base Station 186.The GSM Base Station 186 also includes a GSM transceiver 182 and GSM frequency hopping logic 926.The GSM frequency hopping logic 608 in the wireless communications device 100B is required to switch to a frequency-hopping mode when the GSM Base Station 186 tells it to do so. Currently, GSM networks utilize frequency hopping all the time, not only in case of interference. The GSM frequency hopping logic 608 in the wireless communications device 100B performs the frequency hopping operation when the GSM base station 186 controller commands it to do so. When the GSM base station 186 commands the wireless communications device 100B to turn on frequency hopping, it assigns the wireless communications device 100B a full set of RF channels rather than a single RF channel. The GSM frequency hopping logic 608 in the wireless communications device 100B performs the frequency hopping operation on the assigned set of frequencies to satisfy the command from the base station.

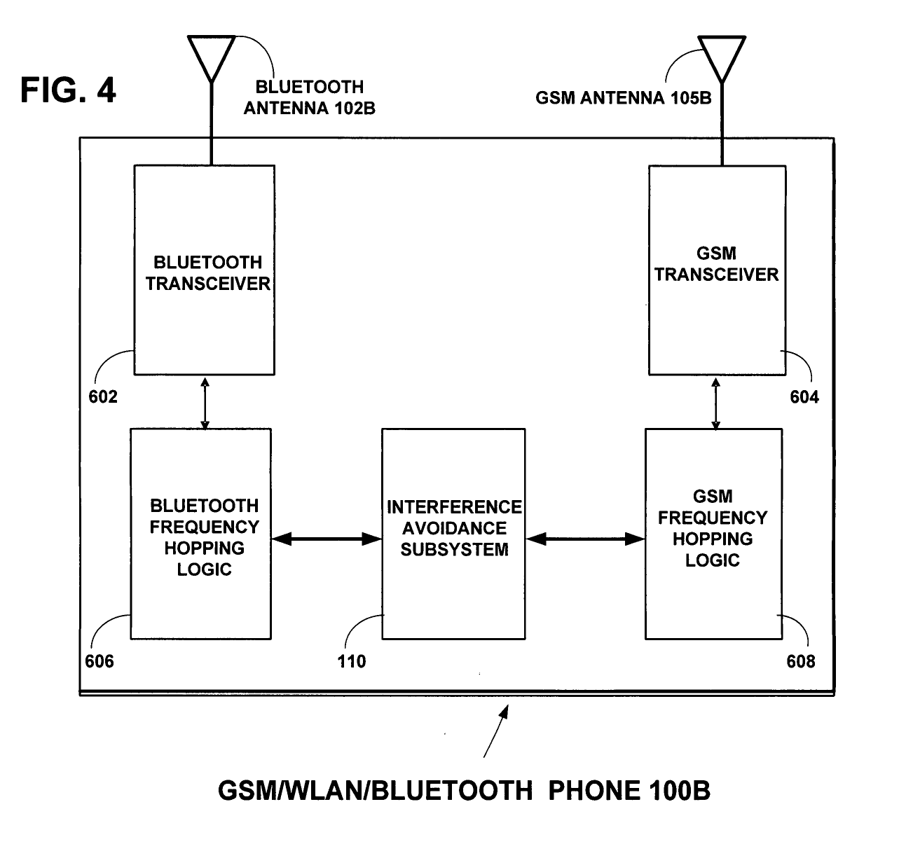

FIG. 4 is a functional block diagram of the GSM/WLAN/Bluetooth wireless communications device 100B, including an interference avoidance subsystem 110 connected between he GSM frequency hopping logic 608 and the Bluetooth frequency hopping logic 606, according to an embodiment of the present invention. Bluetooth transceiver 602 and GSM transceiver 604 are also shown. Bluetooth frequency hopping information and time domain operation information are input from the Bluetooth frequency hopping logic 606 to the interference avoidance subsystem 110. GSM frequency hopping information and time domain operation information are input from the GSM frequency hopping logic 608 to the interference avoidance subsystem 110. The interference avoidance subsystem 110 then uses this input data to calculate the interference probability between co-existing Bluetooth received signals and GSM transmitted signals. The interference avoidance subsystem 110 then compares the calculated interference probability with the required Bluetooth packet error rate limit for the current application. For example, in a Bluetooth speech coding application using 64 kb/s Continuously Variable Slope Delta (CVSD) modulation, acceptable speech quality can be obtained even with 1-3% bit error rate (BER). In contrast, Bluetooth coding for data traffic can tolerate a higher bit-error rate, since data packets that are determined to be in error can be retransmitted. If the interference probability exceeds the required Bluetooth packet error rate limit, the interference avoidance subsystem 110 sends a signal to the Bluetooth frequency hopping logic 606 to change the Bluetooth frequencies.

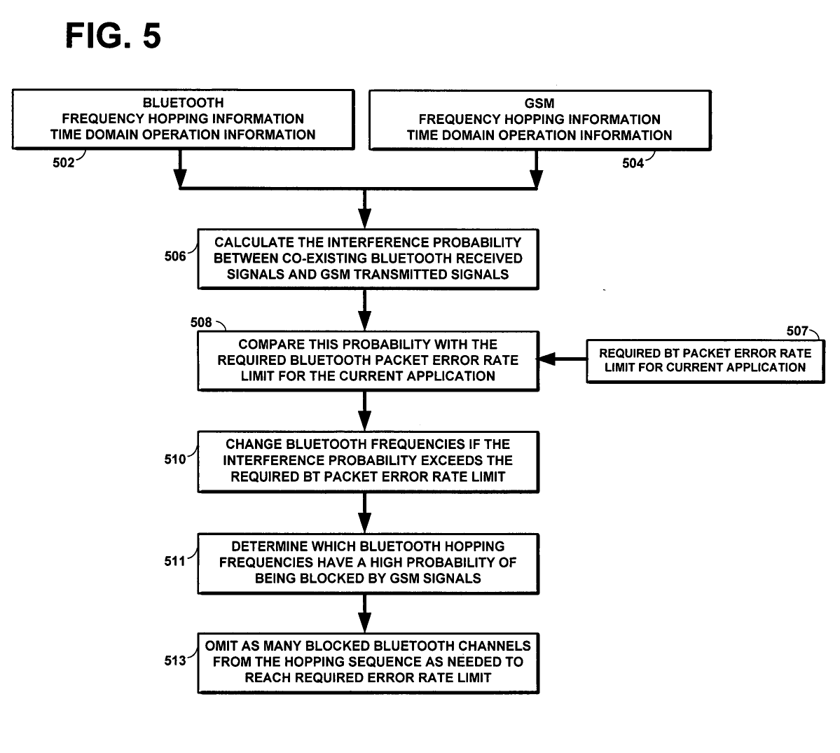

FIG. 5 is a flow diagram of the operation of the interference avoidance subsystem 110 in the GSM/WLAN/Bluetooth wireless communications device 100B for received Bluetooth signals, according to an embodiment of the present invention. The steps of the flow diagram represent programmed sequences of operational instructions which, when executed by computer processor 912 in the wireless communications device 100B, carry out the methods of one embodiment of the invention.

In step 502, Bluetooth frequency hopping information and time domain operation information are input from the Bluetooth frequency hopping logic to the interference avoidance subsystem.

In step 504, GSM frequency hopping information and time domain operation information are input from the GSM frequency hopping logic to the interference avoidance subsystem.

In step 506, the interference avoidance subsystem then uses this input data to calculate the interference probability between co-existing Bluetooth received signals and GSM transmitted signals.

In step 508, the interference avoidance subsystem then compares the calculated interference probability with the required Bluetooth packet error rate limit for the current application, from step 507.

Instep 510, if the interference probability exceeds the required Bluetooth packet error rate limit, the interference avoidance subsystem sends a signal to the Bluetooth frequency hopping logic to change the Bluetooth frequencies (also referred to as channels).

The interference avoidance subsystem 110 calculates the probability of interference a priori. The interference avoidance subsystem 110 uses this principle to limit the Bluetooth hopping frequencies by determining in step 511 which channels in the hopping sequence have a high probability of being blocked by the GSM harmonics and then omitting in step 513 as many of the blocked Bluetooth channels from the hopping sequence as needed to reach the required error rate criterion.

Alternately, the interference avoidance subsystem can optionally perform a loop from step 510 back to step 502, to progressively remove the top frequency Bluetooth channels and to recalculate the interference probability until the magnitude of the interference probability is sufficiently reduced so as to not exceed the required error rate limit.

In another embodiment of the invention, the interference avoidance subsystem 110 can progressively restore some or all of the top frequency Bluetooth channels if the recalculation of the interference probability shows that the magnitude of the interference probability is reducing so as to be significantly less than the required Bluetooth error rate limit. This can occur, for example, if the GSM channel assignments are changed by the GSM base station, thereby moving the interfering GSM spectrum so that it no longer overlaps the ISM spectrum.

In another embodiment of the invention, the short range wireless communications unit can input a received signal quality value in the calculation of the interference probability, for signals received by the short range wireless communications unit.

In another embodiment of the invention, the interference avoidance subsystem can calculate an instant when the interference will occur. In response, the interference avoidance subsystem will change one of the co-existing signals at that instant if the interference probability exceeds the required error rate limit.

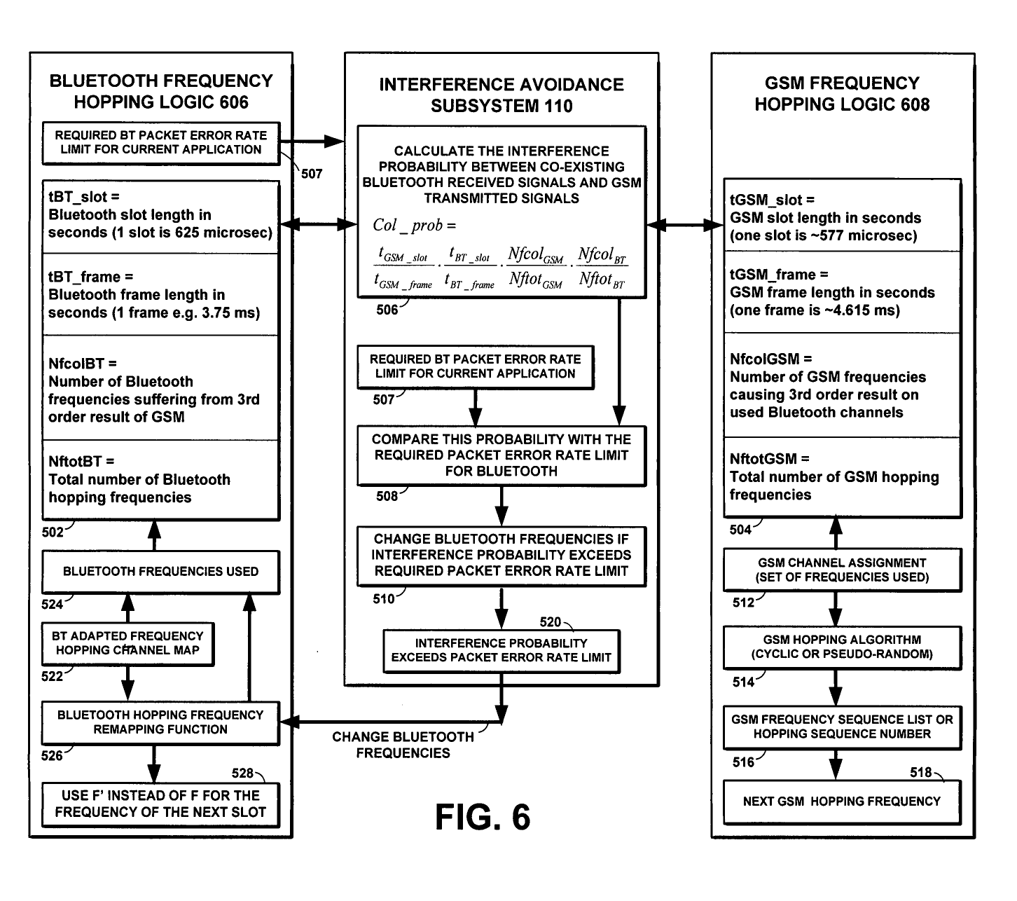

FIG. 6 is a more detailed functional block diagram of the GSM/WLAN/Bluetooth wireless communications device, showing how the interference avoidance subsystem 110 interacts with the Bluetooth frequency hopping logic 606 and the GSM frequency hopping logic 608 to carry out the operation of the flow diagram of FIG. 5, according to an embodiment of the present invention.

In step 502, Bluetooth frequency hopping information and time domain operation information are input from the Bluetooth frequency hopping logic 606 to the interference avoidance subsystem 110 m as follows:
tBT_slot=Bluetooth slot length in seconds (one slot is 625 microsecs)
tBT_frame=Bluetooth frame length in seconds (one frame is e.g. 3.75 ms)
NfcolBT=Number of Bluetooth channels suffering from 3rd order result of GSM
NftotBT=Total number of Bluetooth hopping channels.

The Bluetooth adapted frequency channel map 522 normally provides the 32 channels to be used out of the 79 possible channels, over which to perform normal frequency hopping, as defined in the Bluetooth Specification, Vol. 1.2. Normally, these 32 channels from the Bluetooth adapted frequency channel map 522 are passed to the Bluetooth Frequencies Used Register in step 524 and in turn passed to step 502.

In step 504, GSM frequency hopping information and time domain operation information are input from the GSM frequency hopping logic 608 to the interference avoidance subsystem 110, as follows.
tGSM_slot=GSM slot length in seconds (one slot is ˜577 microsecs)
tGSM_frame=GSM frame length in seconds (one frame is ˜4.615 ms)
NfcolGSM=Number of GSM channels causing 3rd order result on used Bluetooth channels
NftotGSM=Total number of GSM hopping channels.

The data in step 504 is provided by the GSM channel assignment step 512, which identifies the set of frequencies used in the GSM frequency hopping operation. The GSM hopping algorithm step 514 can be either cyclic or pseudo-random. A GSM frequency sequence list in step 516 is used in the cyclic hopping algorithm. A GSM hopping sequence number in step 516 is used in the pseudo-random hopping algorithm. The output of the GSM hopping algorithm yields the next GSM hopping frequency in step 518.

In step 506, the interference avoidance subsystem then uses this input data to calculate the interference probability, Col_prob, between co-existing Bluetooth received signals and GSM transmitted signals, as follows.

$$Col\_prob = \frac{{t}_{GSM\_slot}}{{t}_{GSM\_frame}} \cdot \frac{{t}_{BT\_slot}}{{t}_{BT\_frame}} \cdot \frac{{Nfcol}_{GSM}}{{Nftot}_{GSM}} \cdot \frac{{Nfcol}_{BT}}{{Nftot}_{BT}}$$

In step 508, the interference avoidance subsystem 110 then compares the calculated interference probability, Col_prob, with the required Bluetooth packet error rate limit for the current application, from step 507.

Instep 510, if the interference probability, Col_prob, exceeds the required Bluetooth packet error rate limit, the interference avoidance subsystem 110 sends a signal from step 520 to step 526 in the Bluetooth frequency hopping logic 606 to remap the Bluetooth hopping frequency.

The interference avoidance subsystem 110 and the Bluetooth frequency hopping logic 606 limits the Bluetooth hopping frequencies by calculating which channels are blocked by the GSM harmonics and then omitting as many of the blocked Bluetooth channels from the hopping sequence as needed to reach the required error rate criterion.

The Bluetooth adapted frequency channel map 522 normally provides the 32 channels to be used out of the 79 possible channels, over which to perform normal frequency hopping, as defined in the Bluetooth Specification, Vol. 1.2. Normally, these 32 channels from the Bluetooth adapted frequency channel map 522 are passed to the Bluetooth Frequencies Used Register in step 524 and in turn passed to step 502. However, when the interference avoidance subsystem 110 sends a signal from step 520 to step 526 in the Bluetooth frequency hopping logic 606 to remap the Bluetooth hopping frequency, the remapped channels from Bluetooth hopping frequency remapping function 526 change the data in step 502.The remapped channels from Bluetooth hopping frequency remapping function 526 are passed to the Bluetooth Frequencies Used Register in step 524 and in turn are passed to step 502 to be used in the next calculation of the interference probability, Col_prob.

In Bluetooth adapted frequency hopping (AFH) operation, the possibility of altering used channels in the Bluetooth hopping sequence depends on whether the Bluetooth communications unit is operating as a master or slave. In the case of operating as a master, it can update the AFH_channel_map—parameter. This parameter contains a list of used and unused frequencies. The interference avoidance subsystem 110 can set the channels suffering the interference as unused-channels. In the case of the Bluetooth communications unit operating as a slave, the operation is more complex. The master can be programmed to selectively request the slave to report its good and bad channels using the AFH_classification_slave—parameter. Typically this is done during the connection setup phase. The slave can then report the channels suffering the interference as bad channels. The master can be programmed to selectively utilize the channel report from slave.

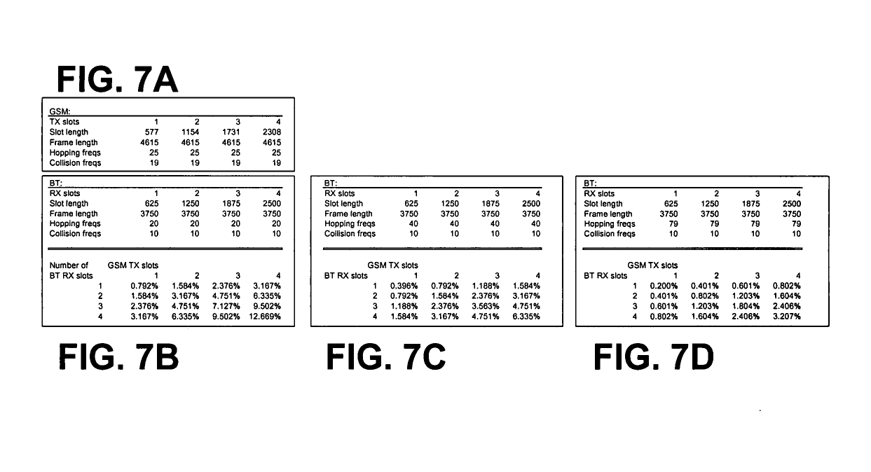

FIGS. 7A to 7D are tables showing the calculated interference probability, Col_prob, computed by the interference avoidance subsystem 110 for the case where the wireless communications device 100B transmits a GSM signal using a 5 MHz operator frequency allocation (TX: 824-829 MHz) for hopping (25 channels) and the wireless communications device receives Bluetooth signals at various example hopping frequencies (min 20, max 79), according to an embodiment of the present invention. The collision probability in case where all 79 Bluetooth frequencies are available is 0.2% in case of single slot transmission. If the packet error requirement for speech link is, e.g. 3%, the 0.2% alleviation does not justify the blocking of the uppermost Bluetooth channels. When there are, e.g. WLAN access points utilizing the same frequency region as Bluetooth, some channels are not usable. In this case, Bluetooth may end up using only a minimum set of hopping frequencies (20) leading to 0.8% collision probability. This negatively affects the 3% total packet error rate, meaning that it is useful at this point to start limiting the used Bluetooth frequencies. Similar calculations can be made for all combinations of slot numbers, packet error rates, hopping frequencies, etc.

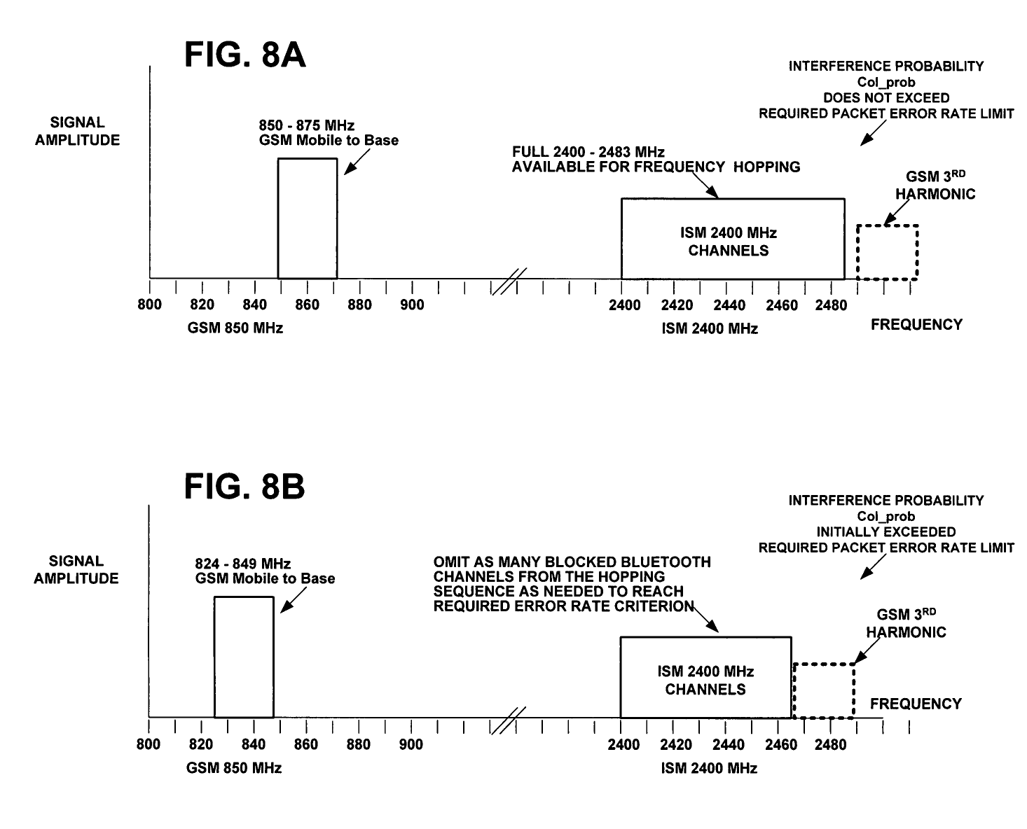

FIG. 8A is a diagram of the frequency spectrum for a 850-875 MHz GSM Mobile to Base transmission, showing that there is no overlap of its third harmonic with the frequency spectrum for signals received in the 2400-2483 MHz ISM (Bluetooth & 802.11) spectrum and thus, in this case, the interference probability computed by the interference avoidance subsystem does not exceed the required Bluetooth packet error rate limit, and therefore the full 2400 to 2483 MHz ISM spectrum is available for Bluetooth frequency hopping, according to an embodiment of the present invention.

FIG. 8B is a diagram of the frequency spectrum for a 824-849 MHz GSM Mobile to Base transmission, showing that there is an overlap of its third harmonic with the frequency spectrum for signals received in the 2400-2483 MHz ISM (Bluetooth & 802.11) spectrum and thus, in this overlapped case, the interference probability computed by the interference avoidance subsystem exceeds the required packet error rate limit. The interference avoidance subsystem calculates the probability of interference a priori. The interference avoidance subsystem uses this principle to limit the Bluetooth hopping frequencies by calculating which channels are blocked by the GSM harmonics and then omitting as many of the blocked Bluetooth channels from the hopping sequence as needed to reach the required error rate criterion, according to an embodiment of the present invention.

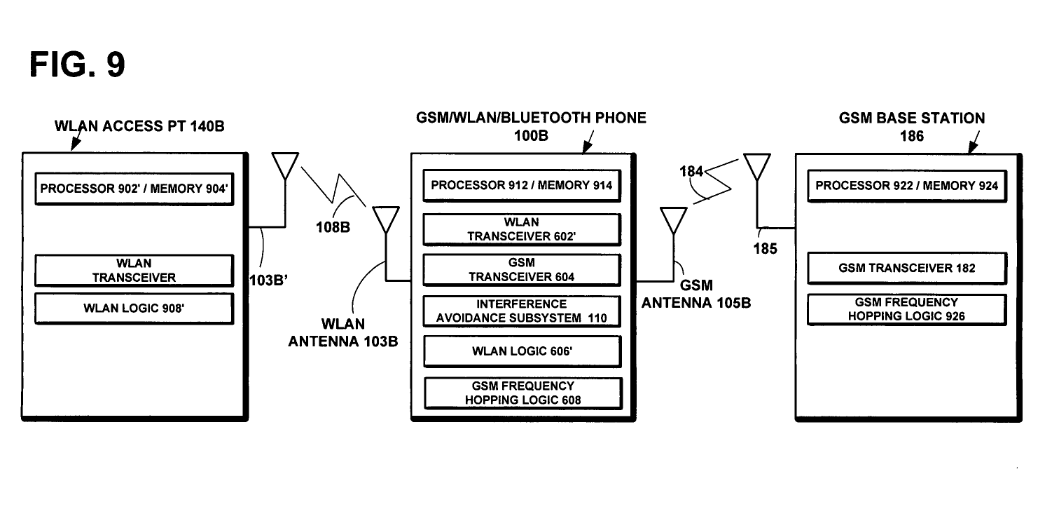

FIG. 9 is a network diagram that shows the wireless network relationship of the WLAN access point 140B, the GSM/WLAN/Bluetooth wireless communications device 100B, and the GSM Base Station 186, according to an embodiment of the present invention. The WLAN access point 140B includes a processor 902′ that executes program instructions stored in the memory 904′ to carry out the functions of the WLAN access point 140B. The WLAN access point 140B includes a WLAN transceiver and a WLAN logic 908′. The GSM/WLAN/Bluetooth wireless communications device 100B includes a processor 912 that executes program instructions stored in the memory 914 to carry out the functions of the wireless communications device 100B. The wireless communications device 100B also includes a WLAN transceiver 602′, a GSM transceiver 604, interference avoidance subsystem 110, WLAN logic 606′, and GSM frequency hopping logic 608.The GSM Base Station 186 includes a processor 922 that executes program instructions stored in the memory 924 to carry out the functions of the GSM Base Station 186. The GSM Base Station 186 also includes a GSM transceiver 182 and GSM frequency hopping logic 926.

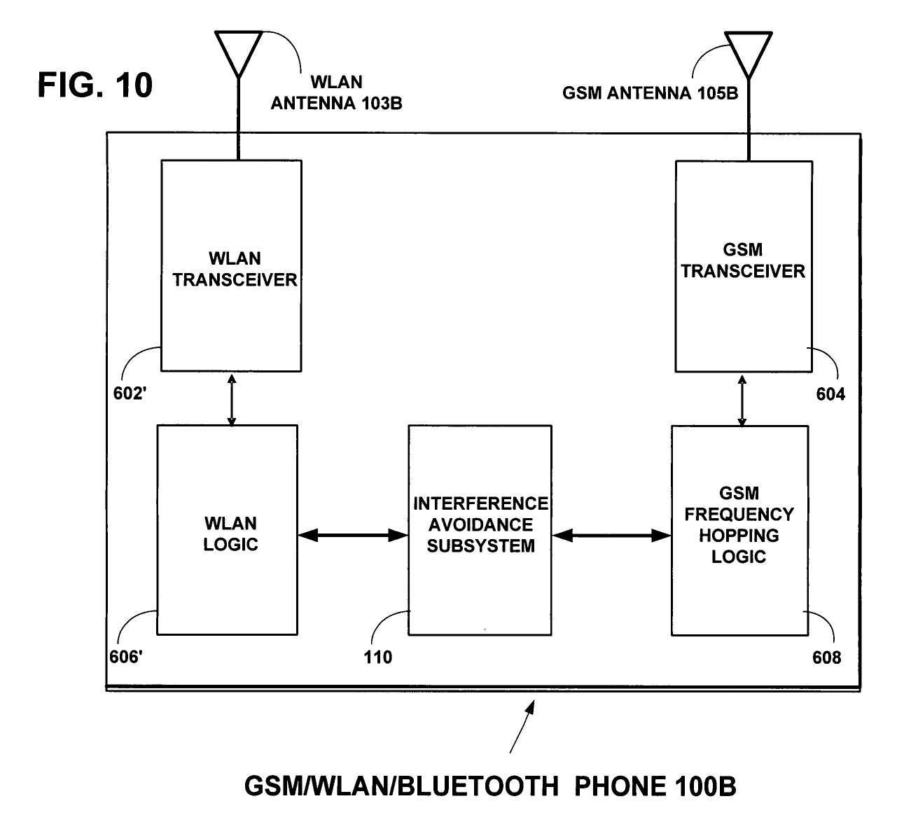

FIG. 10 is a functional block diagram of the GSM/WLAN/Bluetooth wireless communications device 100B, including an interference avoidance subsystem 110 connected between the GSM frequency hopping logic 608 and the WLAN logic 606′, according to an embodiment of the present invention. WLAN transceiver 602′ and GSM transceiver 604 are also shown. WLAN frequency hopping information and time domain operation information are input from the WLAN logic 606′ to the interference avoidance subsystem 110. GSM frequency hopping information and time domain operation information are input from the GSM frequency hopping logic 608 to the interference avoidance subsystem 110. The interference avoidance subsystem 110 then uses this input data to calculate the interference probability between co-existing WLAN received signals and GSM transmitted signals. The interference avoidance subsystem 110 then compares the calculated interference probability with the required WLAN packet error rate limit for the current application. For example, in a WLAN speech coding application, acceptable speech quality generally requires a lower bit error rate (BER) than WLAN coding for data traffic, since data packets that are determined to be in error can be retransmitted. If the interference probability exceeds the required WLAN packet error rate limit, the interference avoidance subsystem 110 sends a signal to the WLAN logic 606′ to change the WLAN frequencies.

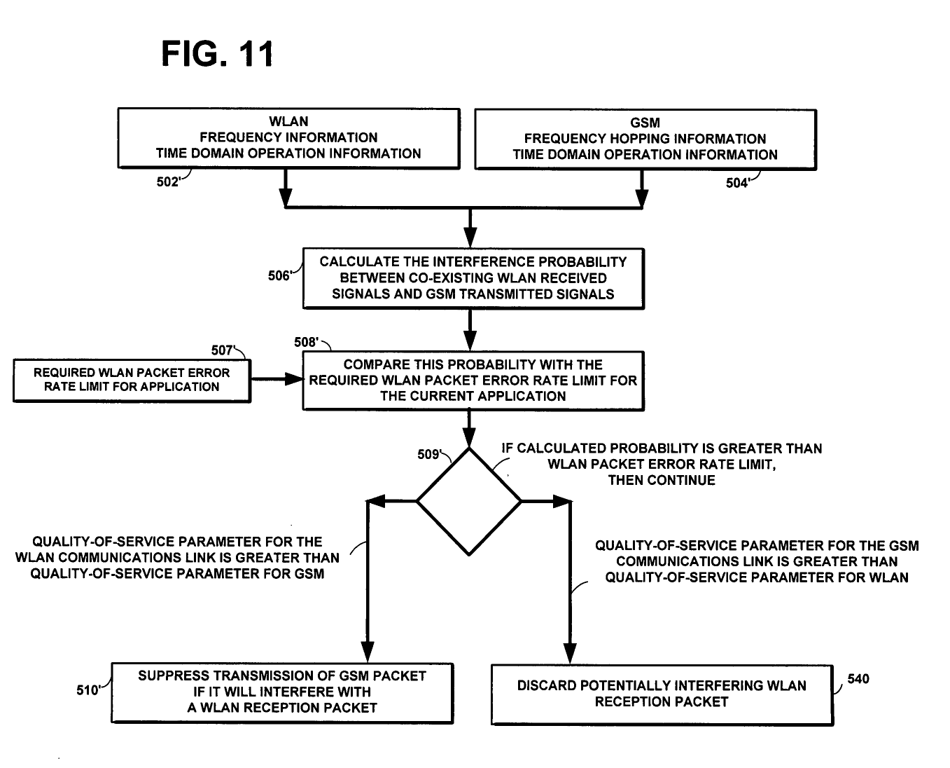

FIG. 11 is a flow diagram of the of the operation of the interference avoidance subsystem 110 in the GSM/WLAN/Bluetooth wireless communications device 100B for received WLAN signals that do not engage in frequency hopping, according to an embodiment of the present invention. In the case where the WLAN communications unit of the wireless communications device is not operating in a frequency hopping mode, the method of the invention operates, for example, as follows.

The steps of the flow diagram represent programmed sequences of operational instructions which, when executed by computer processor 912 in the wireless communications device 100B, carry out the methods of one embodiment of the invention.

In step 502′, WLAN frequency information and time domain operation information are input from the WLAN logic 606′ to the interference avoidance subsystem 110. The WLAN packet length in seconds depends on the connection parameters and is defined case by case. The same applies also for the WLAN packet repetition rate In step 502′, WLAN frequency information and time domain operation information are input from the WLAN logic 606′ to the interference avoidance subsystem 110 as follows:
tWL_slot=WLAN slot length in seconds
tWL_frame=WLAN frame length in seconds
NfcolWL=Number of WLAN frequencies suffering from 3rd order result of GSM
NftotWL=Total number of WLAN hopping frequencies (in this example=1).

In step 504′, GSM frequency hopping information and time domain operation information are input from the GSM frequency hopping logic 608 to the interference avoidance subsystem 110, as follows.
tGSM_slot=GSM slot length in seconds (one slot is ˜577 microsec)
tGSM_frame=GSM frame length in seconds (one frame is ˜4.615 ms)
NfcolGSM 32 Number of GSM frequencies causing 3rd order result on used WLAN channels
NftotGSM 32 Total number of GSM hopping frequencies (in this example=25).

In step 506′, the interference avoidance subsystem then uses this input data to calculate the interference probability, Col_prob, between co-existing WLAN received signals and GSM transmitted signals, as follows:

$$Col\_prob = \frac{{t}_{GSM\_slot}}{{T}_{GSM\_frame}} \cdot \frac{{T}_{WL\_slot}}{{T}_{WL\_frame}} \cdot \frac{{Nfcol}_{GSM}}{{Nftot}_{GSM}} \cdot \frac{{Nfcol}_{WL}}{{Nftot}_{WL}}$$

The interference avoidance subsystem 110 calculates the interference probability between co-existing WLAN received signals and GSM transmitted signals with the WLAN hopping frequencies set equal to one. The number of GSM hopping frequencies used by the interference avoidance subsystem in calculating the interference probability with WLAN signals is similar to that previously discussed above in the case of Bluetooth. The GSM hopping frequencies used in calculating the interference probability the depend on the GSM operator frequency allocation and the number of frequencies in the hopping sequence causing an intermodulation distortion (IMD) result on top of the WLAN reception.

In step 508′, the interference avoidance subsystem 110 then compares the calculated interference probability, Col_prob, with the required WLAN packet error rate limit for the current application, from step 507′. Step 509′, if the calculated probability is greater than the WLAN packet error rate limit, then the process continues, otherwise no change is made to reduce interference.

In accordance with another embodiment of the invention, in step 509′the interference avoidance subsystem can compare a Quality-of-Service (QoS) parameter for the WLAN communications link with a Quality-of-Service parameter for the GSM link to determine whether potentially interfering WLAN reception packets should be discarded in step 510′, as opposed to an alternative mode of the interference avoidance subsystem signaling in step 540 to the GSM communications unit to suppress transmission a GSM packet if it will interfere with a WLAN reception packet.

In step 509′, if the calculated interference probability is greater than the predefined error probability or packet error rate limit, then the interference avoidance subsystem 110 signals the WLAN communications unit to discard the WLAN reception packet in step 510′. Step 510′ can be augmented by discarding the WLAN packet if the received packet is detected by the WLAN communications unit as being corrupted. The discarding step 510′ results in the WLAN communications unit not transmitting an acknowledgement packet back to the sender, WLAN access point 140B. Typically, the WLAN protocol will then require the sender to retransmit the packet, which most probably will not occur simultaneously with following GSM transmissions and will be correctly received by the WLAN communications unit. If the reception packet detected by the WLAN communications unit is not corrupted, then the received packet may be suspected of containing erroneous data. Optionally, in step 510′, the WLAN communications unit can discard the WLAN reception packet in this case, as well, and force a retransmission of the packet from the sender. Another option is for the WLAN communications unit to direct a received WLAN packet that is suspected of containing erroneous data, into a suspicious-packet-buffer for additional error checking or tagging.

In another embodiment of the invention shown in FIG. 11, where the WLAN communications link does not engage in frequency hopping, interference with a WLAN reception packet is avoided by the interference avoidance subsystem signaling in step 540 to the GSM communications unit to suppress transmission a GSM packet if it will interfere with the WLAN reception packet.

In an alternate embodiment of the invention, the GSM hopping frequencies can be changed to reduce the interference. The GSM frequencies can be changed if the interference probability exceeds the required WLAN packet error rate limit. In an alternate embodiment of the invention, step 540 can loop back to step 504′ to progressively change the interfering frequency GSM channels and recalculate the interference probability until the magnitude of the interference probability is sufficiently reduced so as to not exceed the required WLAN error rate limit. This enables avoiding transmitting in certain GSM channels due to interference with WLAN reception. The packet error rate of particular service can be taken into account by allocating e.g. 10% budget of the total packet error rate to the interference.

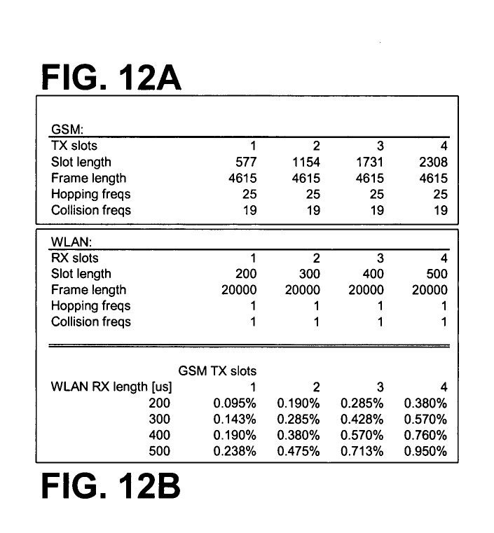

FIGS. 12A and 12B are tables showing the calculated interference probability computed by the interference avoidance subsystem for the case where the wireless communications device transmits a GSM signal using a 5 MHz operator frequency allocation (TX: 824-829 MHz) for hopping (25 channels) and the wireless communications device receives WLAN VoIP signals, according to an embodiment of the present invention.

The resulting invention has the following advantages:
Much better utilization of available frequencies
Enhanced capacity, especially in case of crowded 2.4GHz ISM-band
Adaptive operation
Takes into account the service packet error requirements in the interference avoidance
Easy to implement, no complex decision logic needed
Better user experience
The basic idea can be utilized to many different radio combinations causing interoperability problems

Although specific embodiments of the invention have been disclosed, a person skilled in the art will understand that changes can be made to the specific embodiments without departing from the spirit and scope of the invention.

What is claimed is:

1. A method in a wireless communications device to reduce interference between a wireless telephone unit and a short range wireless communications unit contained therein, comprising:
inputting frequency information and time domain operation information from the short range wireless communications unit;
inputting frequency hopping information and time domain operation information from the wireless telephone unit;
calculating an interference probability between co-existing signals received by the short range wireless communications unit and transmitted from the wireless telephone unit;
comparing the calculated interference probability with a required error rate limit for the short range wireless communications unit; and
changing one of the co-existing signals in either the short range wireless communications unit or the wireless telephone unit if the interference probability exceeds the required error rate limit.

2. The method of claim 1, which further comprises:
inputting frequency hopping information from the short range wireless communications unit;
determining which hopping frequencies in a hopping sequence of said short range wireless communications unit have a high probability of being blocked by signals transmitted from the wireless telephone unit; and
omitting the blocked hopping frequencies from the hopping sequence to reach the required error rate limit.

3. The method of claim 2, which further comprises:
said short range wireless communications unit is a Bluetooth communications device and said wireless telephone unit is a GSM telephone.

4. The method of claim 1, which further comprises:
said short range wireless communications unit is a WLAN communications device and said wireless telephone unit is a GSM telephone.

5. The method of claim 1, which further comprises:
said short range wireless communications unit is a WLAN communications device using only a single channel frequency to receive a WLAN signal;
discarding a received WLAN signal if said calculated interference probability is greater than the required error rate limit.

6. The method of claim 5, which further comprises:
said discarding occurring only if the received WLAN signal is corrupted.

7. The method of claim 1, which further comprises:
said short range wireless communications unit is a WLAN communications device using only a single channel frequency to receive a WLAN signal;
suppressing transmission a signal from said wireless telephone unit if said calculated interference probability is greater than the required error rate limit.

8. The method of claim 1, which further comprises:
said short range wireless communications unit is a WLAN communications device using only a single channel frequency to receive a WLAN signal;
comparing a Quality-of-Service parameter for the received WLAN signal with a Quality-of-Service parameter for a signal to be transmitted from said wireless telephone unit;
discarding said received WLAN signal if said Quality-of-Service parameter for said wireless telephone unit signal is greater than said Quality-of-Service parameter for said received WLAN signal; and
suppressing transmission a said wireless telephone unit signal if said Quality-of-Service parameter for said wireless telephone unit signal is less than said Quality-of-Service parameter for said received WLAN signal.

9. The method of claim 1, which further comprises:
inputting a received signal quality value in said calculation of the interference probability, for signals received by said short range wireless communications unit.

10. The method of claim 1, which further comprises:
calculating an instant when said interference will occur; and
changing one of the co-existing signals at said instant if the interference probability exceeds the required error rate limit.

11. A wireless communications device, comprising:
a wireless telephone unit contained in a wireless communications device
a short range wireless communications unit contained in the wireless communications device;
an interference avoidance subsystem contained in the wireless communications device, coupled to the wireless telephone unit and the short range wireless communications unit;
said short range wireless communications unit inputting frequency information and time domain operation information to the interference avoidance subsystem;
said wireless telephone unit inputting frequency hopping information and time domain operation information to the interference avoidance subsystem;
said interference avoidance subsystem calculating an interference probability between co-existing signals received by the short range wireless communications unit and transmitted from the wireless telephone unit;
said interference avoidance subsystem comparing the calculated interference probability with a required error rate limit for the short range wireless communications unit; and
said interference avoidance subsystem changing one of the co-existing signals in either the short range wireless communications unit or the wireless telephone unit if the interference probability exceeds the required error rate limit.

12. The device of claim 11, which further comprises:
said short range wireless communications unit inputting frequency hopping information to the interference avoidance subsystem;
said interference avoidance subsystem determining which hopping frequencies in a hopping sequence of said short range wireless communications unit have a high probability of being blocked by signals transmitted from the wireless telephone unit; and
said short range wireless communications unit omitting the blocked hopping frequencies from the hopping sequence to reach the required error rate limit.

13. The device of claim 12, which further comprises:
said short range wireless communications unit is a Bluetooth communications device and said wireless telephone unit is a GSM telephone.

14. The device of claim 11, which further comprises:
said short range wireless communications unit is a WLAN communications device and said wireless telephone unit is a GSM telephone.

15. The device of claim 11, which further comprises:
said short range wireless communications unit is a WLAN communications device using only a single channel frequency to receive a WLAN signal;
said interference avoidance subsystem discarding a received WLAN signal if said calculated interference probability is greater than the required error rate limit.

16. The device of claim 15, which further comprises:
said discarding occurring only if the received WLAN signal is corrupted.

17. The device of claim 11, which further comprises:
said short range wireless communications unit is a WLAN communications device using only a single channel frequency to receive a WLAN signal;
said interference avoidance subsystem suppressing transmission a signal from said wireless telephone unit if said calculated interference probability is greater than the required error rate limit.

18. The device of claim 11, which further comprises:
said short range wireless communications unit is a WLAN communications device using only a single channel frequency to receive a WLAN signal;
said interference avoidance subsystem comparing a Quality-of-Service parameter for the received WLAN signal with a Quality-of-Service parameter for a signal to be transmitted from said wireless telephone unit;
said interference avoidance subsystem discarding said received WLAN signal if said Quality-of-Service parameter for said wireless telephone unit signal is greater than said Quality-of-Service parameter for said received WLAN signal; and
said interference avoidance subsystem suppressing transmission a said wireless telephone unit signal if said Quality-of-Service parameter for said wireless telephone unit signal is less than said Quality-of-Service parameter for said received WLAN signal.

19. The device of claim 11, which further comprises:
said short range wireless communications unit inputting a received signal quality value in said calculation of the interference probability, for signals received by said short range wireless communications unit.

20. The device of claim 11, which further comprises:
said interference avoidance subsystem calculating an instant when said interference will occur; and
said interference avoidance subsystem changing one of the co-existing signals at said instant if the interference probability exceeds the required error rate limit.

21. A computer program product for a wireless communications device to reduce interference between a wireless telephone unit and a short range wireless communications unit contained therein, comprising:
a computer readable medium;
program code in the computer readable medium for inputting frequency information and time domain operation information from the short range wireless communications unit;
program code in the computer readable medium for inputting frequency hopping information and time domain operation information from the wireless telephone unit;
program code in the computer readable medium for calculating an interference probability between co-existing signals received by the short range wireless communications unit and transmitted from the wireless telephone unit;
program code in the computer readable medium for comparing the calculated interference probability with a required error rate limit for the short range wireless communications unit; and
program code in the computer readable medium for changing one of the co-existing signals in either the short range wireless communications unit or the wireless telephone unit if the interference probability exceeds the required error rate limit.

22. The computer program product of claim 21, which further comprises:
program code in the computer readable medium for inputting frequency hopping information from the short range wireless communications unit;
program code in the computer readable medium for determining which hopping frequencies in a hopping sequence of said short range wireless communications unit have a high probability of being blocked by signals transmitted from the wireless telephone unit; and
program code in the computer readable medium for omitting the blocked hopping frequencies from the hopping sequence to reach the required error rate limit.

23. The computer program product of claim 22, which further comprises:
said short range wireless communications unit is a Bluetooth communications device and said wireless telephone unit is a GSM telephone.

24. The computer program product of claim 21, which further comprises:
said short range wireless communications unit is a WLAN communications device and said wireless telephone unit is a GSM telephone.

25. The computer program product of claim 21, which further comprises:
said short range wireless communications unit is a WLAN communications device using only a single channel frequency to receive a WLAN signal;
program code in the computer readable medium for discarding a received WLAN signal if said calculated interference probability is greater than the required error rate limit.

26. The computer program product of claim 25, which further comprises:
said discarding occurring only if the received WLAN signal is corrupted.

27. The computer program product of claim 21, which further comprises:
said short range wireless communications unit is a WLAN communications device using only a single channel frequency to receive a WLAN signal;
program code in the computer readable medium for suppressing transmission a signal from said wireless telephone unit if said calculated interference probability is greater than the required error rate limit.

28. The computer program product of claim 21, which further comprises:
said short range wireless communications unit is a WLAN communications device using only a single channel frequency to receive a WLAN signal;
program code in the computer readable medium for comparing a Quality-of-Service parameter for the received WLAN signal with a Quality-of-Service parameter for a signal to be transmitted from said wireless telephone unit;
program code in the computer readable medium for discarding said received WLAN signal if said Quality-of-Service parameter for said wireless telephone unit signal is greater than said Quality-of-Service parameter for said received WLAN signal; and
program code in the computer readable medium for suppressing transmission a said wireless telephone unit signal if said Quality-of-Service parameter for said wireless telephone unit signal is less than said Quality-of-Service parameter for said received WLAN signal.

29. The computer program product of claim 21, which further comprises:
program code in the computer readable medium for inputting a received signal quality value in said calculation of the interference probability, for signals received by said short range wireless communications unit.

30. The computer program product of claim 21, which further comprises:
program code in the computer readable medium for calculating an instant when said interference will occur; and
program code in the computer readable medium for changing one of the co-existing signals at said instant if the interference probability exceeds the required error rate limit.
